(19) United States
(12) Patent Application Publication
(10) Pub. No.: US 2018/0313923 A1
(43) Pub. Date: Nov. 1, 2018

(54) COMBINED IMAGING SYSTEM AND MRI COMPATIBLE LASER SCANNING MICROSCOPE

(71) Applicant: Femtonics Kft., Budapest (HU)

(72) Inventors: Balazs Rozsa, Budapest (HU); Gergely Katona, Budapest (HU)

(21) Appl. No.: 15/527,926

(22) PCT Filed: Nov. 18, 2015
(86) PCT No.: PCT/HU2015/000072

§ 371 Date: May 18, 2017

(30) Foreign Application Priority Data
Nov. 18, 2014 (HU) P1400542

(51) Int. Cl. G01R 33/48; G01T 1/164; G02B 21/00

(52) U.S. Cl. CPC G01R 33/4808; G02B 21/0048; G02B 21/0032; G01T 1/1642

(57) ABSTRACT

The subject of the invention relates to a combined imaging system (10′) that includes a laser scanning microscope (50, 50′), and a measuring device with a lower resolution than the resolution of the laser scanning microscope (50, 50′) and that measures over a larger spatial scale than the spatial scale of the laser scanning microscope (50, 50′). The subject of the invention also relates to an MRI compatible laser scanning microscope which comprises: deflecting means (24′) for deflecting a laser beam (13), objective (28′), adjustable objective arm (38), distance adapter (39) and at least one detector (30′). The essence of the MRI compatible laser scanning microscope is that at least the objective (28′), the adjustable objective arm (38), the distance adapter (39) and the at least one detector (30′) are made from non-magnetisable materials and the deflecting means (24′) is magnetically shielded.

The subject of the present invention is a combined imaging system which comprises a SPECT device and a laser scanning microscope.

The subject of the present invention is also a combined imaging system which comprises an MRI device and a laser scanning microscope.

The subject of the present invention is an MRI compatible laser scanning microscope which comprises:
deflecting means for deflecting a laser beam,
objective,
adjustable objective arm, and
at least one detector

The essence of the invention is that at least the objective, the adjustable objective arm and the at least one detector are made from non-magnetisable material and the deflecting means is magnetically shielded.

The risk of the development of neurological disorders, such as stroke, is increased by risk factors, such as old age, atherosclerosis, diabetes and various infections, which involve a high inflammatory burden after brain injury and therefore increase the extent of nerve injury. Although there is a clear link between neuroinflammatory events and brain injuries, current imaging techniques used in clinical practice are unable to separate inflamed regions of the brain and correlate them with cell-level processes. Beside this, it may also be shown that excitotoxic processes (damaging the nerve cells) do not develop immediately, but gradually, and according to our results the inflammatory processes play a special role in this by changing the network activity between nerve cells. In this way, in the few hours following a stroke there would still be an opportunity to reduce permanent brain damage.

Therefore, it is a very important task to examine the mechanism of inflammatory processes in neurological disorders, and examine these in experimental animal models, for which it is necessary to create a preclinical imaging device. With the help of this it would become possible to develop an early diagnostic imaging device. The problem is made more difficult by that the size and location of the inflamed areas may differ depending on the patient and on occasion there may be great differences in the dynamics of the course of the inflammations. Brain injury after stroke may also result in various peripheral complications, including systemic immunosuppression that may lead to infections in the lungs, urinary tract and other organs, which profoundly influence the chances of survival and recovery of patients. Rapid diagnosis of inflammation processes and post-stroke infections plays and important role in the elaboration of therapy possibilities.

In current medicine practices, assessment of stroke patients largely relies on CT and MRI to determine brain injury, oedema or signs of haemorrhage. These methods, however, are unsuitable for detecting excitotoxic neuronal injury, pathological neuronal network activity and early inflammatory processes.

On the other hand, using a fast scanning, (particularly multiphoton) laser scanning microscope and Ca++ indicators, it is possible to show that excitotoxic neuronal death is delayed for several hours after stroke. Tracking the propagation of Ca++ waves takes place on the neuronal network level, on the macroscopic scale. Two-photon imaging allows both cellular and network level measurements, however, currently available methods limit imaging to a volume of around a 1 cubic millimetre. This volume is several orders of magnitude smaller than the average extension of the inflammation developed after stroke, especially in the case of the human brain.

Commonly used 3D laser scanning microscopes are either confocal microscopes or two-photon microscopes. In confocal microscope technology a pinhole is arranged before the detector to filter out light reflected from any other plane than the focus plane of the microscope objective. Thereby it is possible to image planes lying at different depths within a sample (e.g. a biological specimen).

Two-photon laser scanning microscopes use a laser light of lower energy, therefore two photons are needed to excite a fluorophore in a quantum event, which results in the emission of a fluorescence photon, which is then detected by a detector. The probability of the near simultaneous absorption of two photons is extremely low, therefore the excitation photons require a high flux, thus two-photon excitation practically only occurs in the focal spot of the laser beam, i.e. a small ellipsoidal volume typically having a size of approximately 300 nm×300 nm×1000 nm. Generally a femtosecond pulsed laser is used to provide the required photon flux for the two-photon excitation, while keeping the average laser beam intensity sufficiently low.

When applying either of the above-mentioned technologies, the 3D scanning can be carried out by moving the sample stage (e.g. via stepping motors), however this method is too complicated to implement when using submerged specimen chambers or when electrical recording is performed on the biological specimen with microelectrodes. Accordingly, in the case of analysing biological specimens it is often preferred to move the focus spot of the laser beam instead of moving the specimen. This can be achieved by deflecting the laser beam to scan different points of a focal plane (XY plane) and by displacing the objective along its optical axis (Z axis), e.g. via a piezo-positioner to change the depth of the focal plane. Several known technologies exist for deflecting the laser beam prior to it entering the objective, e.g. via deflecting mirrors mounted on galvanometric scanners, or via acousto-optic deflectors.

The aim of the invention is to provide a combined imagining system and an MRI compatible laser scanning microscope that has none of the disadvantages of the solutions according to the state of the art, in other words that is able to perform measurements simultaneously in 2 or 3 dimensions of large scale (even extending throughout the entire brain) processes and cell-level changes or changes under cell size, thereby making it possible to perform examinations of inflammatory processes and brain injuries developing during an acute stroke and other neurological disorders.

The aim of the invention is also to describe a method and device that is able to reveal the links between large-scale inflammatory processes and cell-level inflammation mechanisms.

We recognised that by combining a laser scanning microscope with MRI technology, and with computerised tomography, especially with Single-Photon Emission Computerized Tomography (SPECT), the above disadvantages may be overcome, and it becomes possible to perform neuron examinations of functional link changes at a depth never seen to date.

In accordance with the invention the task may be realised with a combined imaging system that contains:
at least one MRI device or at least one CT device, especially a SPECT device and
at least one high-resolution scanning microscope compatible with the MRI or SPECT device, which has a 2-dimensional or 3-dimensional measurement space, and at least a part of the MRI-compatible scanning microscope is of non-magnetisable material.

The advantage of the combined imaging system is that:
by combining the measurement data of the laser scanning microscope in real time with the data of the SPECT and/or MRI device high resolution images are made of the entire brain region thereby examining brain perfusion, perfusion-diffusion mismatch, Ca++ distribution and neuronal activity,
by combining the measurement data of the laser scanning microscope in real time with the data of the SPECT and/or MRI device, it is possible to examine the Ca++ responses of the neurons in the same brain region at the cellular level, their network activity and the behaviour of the main brain inflammation cell types (microglia, astroglia), their state of activity and functional role.

A software programme and/or software programmes are preferably linked to the aforementioned combined imaging device that correlate, store and analyse the data of the laser scanning microscope and of the SPECT and/or MRI in real time.

The preferable embodiments of the invention are specified in the sub-claims.

Further details of the invention are presented in embodiments, with the help of drawings. In the drawings

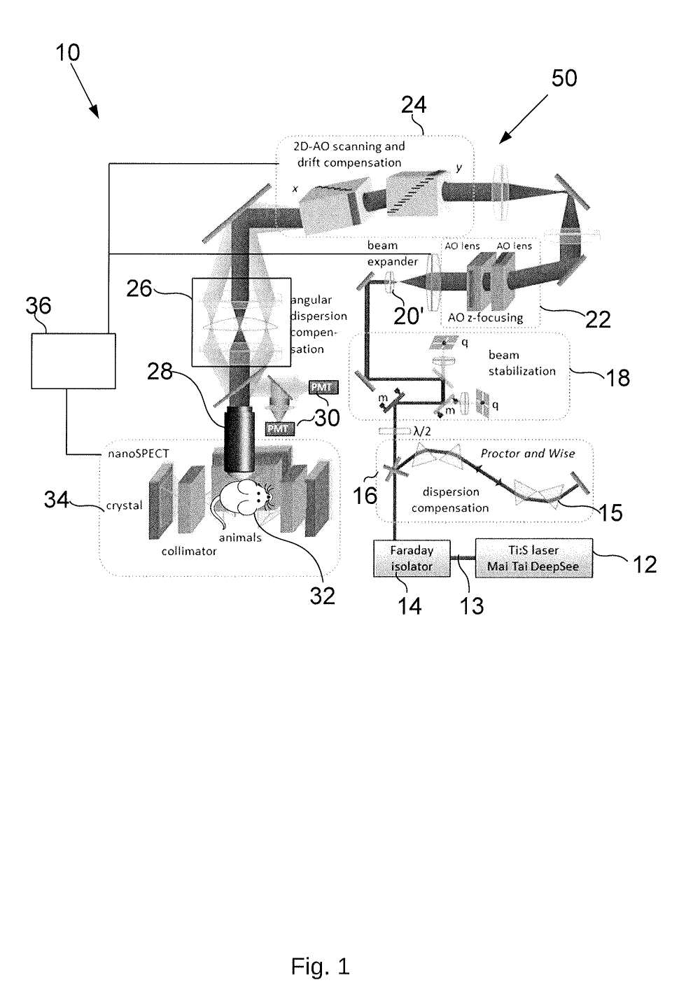

FIG. 1 shows a schematic picture of a preferable embodiment of the combined imaging system according to the invention,

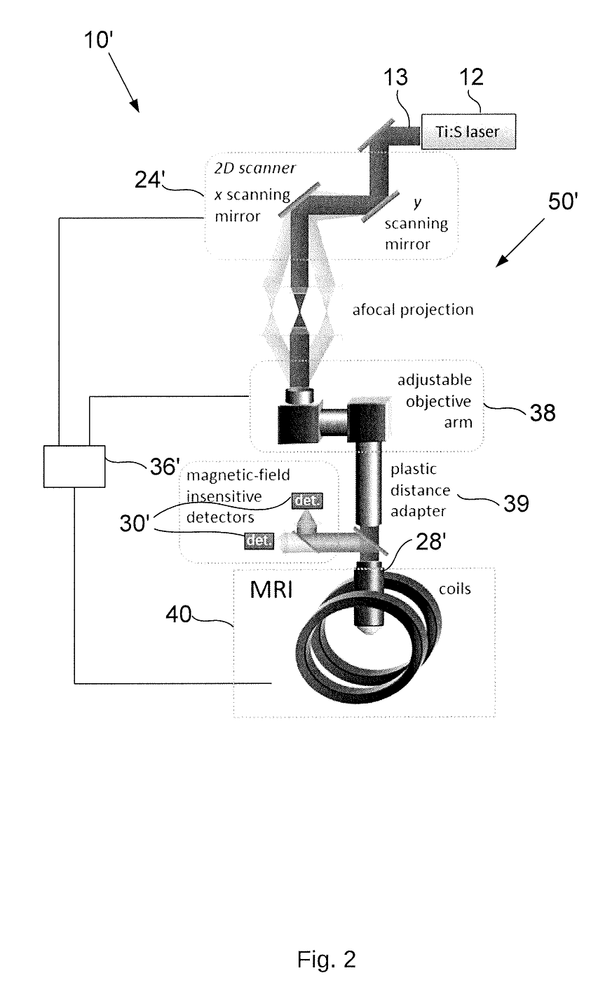

FIG. 2 shows a schematic picture of another preferable embodiment of the combined imaging system according to the invention.

A preferred embodiment of the combined imaging system 10 according to the invention can be seen in FIG. 1. The combined imaging system 10 may advantageously comprises a laser scanning microscope 50, a CT device 34, preferably a SPECT device and a control system 36. The laser scanning microscope 50 contains a laser source 12, which produces a laser beam 13. In the case of this embodiment, the laser scanning microscope 50 also contains a Faraday isolator 14, a dispersion compensation module 16, a laser beam stabilisation module 18, a beam expander 20, an acousto-optic depth focussing device 22, a beam deflecting means 24 that deflects the laser beam 13 in the X and Y directions, an angular dispersion compensation means 26, an objective 28, and photomultiplier detectors 30. Naturally, a laser scanning microscope 50 with a different structure may also be used.

In the case of the embodiment shown in FIG. 1, the depth scanning takes place with the known two-photon excitation technology. It is noted that any other technology may be used in conjunction with the present invention with which various focal depth scanning is possible (e.g. confocal microscope).

The laser source 12 used for two-photon excitation may be a femtosecond pulse laser, e.g. a mode-locked Ti:S laser, which produces the laser beam 13. In such a case the laser beam 13 consists of discrete laser pulses, which pulses have femtosecond pulse width and a repetition frequency in the MHz range.

Preferably a Faraday isolator 14 is located in the optical path of the laser beam 13, which prevents the reflection of the laser beam, thereby aiding smoother output performance. After passing through the Faraday isolator 14, the laser beam passes into the dispersion compensation module 16, in which a pre-dispersion compensation is performed with prisms 15. After this the laser beam 13 passes through the beam stabilisation module 18, and the beam expander 20 and then reaches the acousto-optic depth focussing device 22.

The deflecting means 24 may be any appropriate deflector, e.g. acousto-optic or electro-optic deflector, the latter of which contains scanning mirrors 14′ (mirrors fitted to a galvanometric scanner which deflect the laser beam 13 in the X and Y directions in the given focus plane), etc.

The laser beam 13 deflected by the deflecting means 24 passes through angular dispersion compensation means 26 and reaches the objective 28, which focuses the laser beam 13 onto the sample 32 placed after the objective 28. Preferably a beam splitter 27 is placed between the angular dispersion compensation means 26 and the objective 28, which transmits a part of the laser beam 13 reflected from the sample 32 and collected by the objective 28 to the photomultiplier detector 30, as can be seen in FIG. 1.

The control system 36 performs the control of the deflecting means 24, the acousto-optic depth focussing means 22 and the SPECT device 34. The control system 36 may be an independent unit, e.g. a computer or microcontroller, or may include other control units separately controlling the components of the combined imaging system 10, such as the acousto-optic depth focussing device 22, the deflecting means 24 and the units controlling the SPECT device 34. In the latter case, a main control unit may perform the compilation and analysis of the data (e.g. the feedback information relating to the position) provided by the other control units and the forwarding of the appropriate control signals to the other control units. The control system 36 may be built into the combined imaging system 10, or it may be a separate device, or control software running on a separate device, e.g. computer.

The advantage of the control system 36 is that the SPECT device 34 and the laser scanning microscope 50 may be controlled in a synchronised manner, in this way measurements may be performed simultaneously or with a given time shift, furthermore the synchronised data provided by the SPECT device 34 and the laser scanning microscope 50 can be processed simultaneously in real time, therefore the macroscopic scale and the cell-level processes may be examined at the same time.

FIG. 2 shows a schematic picture of another preferable embodiment of the combined imaging system 10′ according to the invention. The combined imaging system 10′ contains a laser scanning microscope 50′, an MRI device 40 and a control system 36′. In the case of this embodiment the laser scanning microscope 50′ contains a laser source 12, a 2-dimensional deflecting means 24′ moving the beam in the X, Y plane, an objective 28′, adjustable objective arm 38, a distance adapter 39 insensitive to the magnetic field and photomultiplier detectors 30′. Naturally, a laser scanning microscope 50′ with a different structure may also be used.

In the case of the present embodiment, the laser source 12 is a Ti:S laser, which is preferably a laser that can be adjusted to wavelengths between 720-950 nm. The laser source 12 may also include elements that improve the optical properties of the laser beam 13, such as dispersion compensators, Faraday isolators, etc.

The deflecting means 24′ may be any appropriate deflector, e.g. acousto-optic or electro-optic deflector, the latter of which contains scanning mirrors 14′ (mirrors fitted to a galvanometric scanner which deflect the laser beam 13 in the X and Y directions in the given focus plane), etc. Naturally, a 3-dimensional deflecting means 24′ may also be used, for example, in the form of an appropriate acousto-optic deflector system, as it is apparent to a person skilled in the art.

The central part of an MRI device 40 is an electromagnet, and the sample 32 to be examined is placed into its magnetic field. The magnetic field of an MRI 40 is exceptionally strong, the maximum value of the magnetic field strength may exceed 10 Tesla. The strength of the magnetic field determines the resolution of the MRI device 40 as well as the time required for measurement. When using the MRI device 40, the magnetic field created causes the direction of the axis of the protons in the atoms forming the sample 32 to tilt. After the magnetic field is terminated, the protons move back to their original position, while radiating the energy they have received. By measuring the radiated energy a real-time, large-scale image is formed of the sample 32, as is known by a person skilled in the art.

The strength of the magnetic field created determines the resolution of the MRI device 40. Resolution is usually determined in voxels (spatial pixels). The greatest resolution achievable in MRI devices 40 currently in use is 0.1 mm, which is still not sufficient in order to study cell-level processes. The imaging produced using the MRI device 40 is unsuitable for revealing microscopic processes, in other words, no clear correlation may be made between the structures of the sample 32 and the functions belonging to them. Another disadvantage of imaging using an MRI device 40 is that, compared to the fast neurological processes, its temporal resolution is exceptionally bad, which makes examination of the sample 32 difficult.

A preferable embodiment of the combined imaging system 10′ according to the invention contains an MRI device 40 and a laser scanning microscope 50′. We recognised that the laser scanning microscope 50′ has exceptionally good spatial and temporal resolution as compared to an MRI device 40. We recognised that contrast materials exist that provide a satisfactory signal for both an MRI device 40 and a laser scanning microscope 50′ at the same time, therefore, by using the combined imaging system 10′, in other words by combining the two imaging procedures, it becomes unexpectedly possible to simultaneously examine the cell-level (microscopic) processes and the processes taking place in larger regions (macroscopic), and through this the link between the two scales may be revealed.

For example, using the combined imaging system 10′, it is possible to examine excitotoxic neuronal death occurring after a stroke by monitoring the propagation of the Ca++ waves in the brain. We recognised that in order to simultaneously examine the Ca++ waves with an MRI device 40 and a laser scanning microscope 50′, Ca++ indicators (hereinafter contrast material) are required that provide a signal that is detectable by both the MRI device 40 and by the laser scanning microscope 50′. The contrast material used in the case of MRI devices 40 must have paramagnetic or ferromagnetic properties. Another condition is that the contrast material must have low toxicity, be a stable compound and be completely excreted from the body if possible.

We recognised that it is exceptionally preferable to use the isotope of fluorine with mass number 19 as contrast material, the frequency of resonance of which is 94% of that of protium, on which most MRI imaging is based. The isotope of fluorine with mass number 19 also has other preferable characteristics, for example, its NMR sensitivity is 83% and its signal/noise ratio is 89% of that of protium. At the same time, due to the fine structure interaction, the isotope of fluorine with mass number 19 also provides a Ca++ signal for the laser scanning microscope 50′.

Due to the strong magnetic field, the strength of which in a given case may even exceed 10 Tesla, the parts of the laser scanning microscope 50′ of the combined imaging system 10′ arranged in the vicinity of the MRI device 40 preferably contain non-magnetisable materials. The objective 28′ is preferably made from, for example, glass and/or plastic. In the case of an exceptionally preferable embodiment the objective 28′ placed in the magnetic field of the MRI device 40 is connected to the adjustable objective arm 38, which is sufficiently far away from the MRI device 40, using the distance adapter 39 made from non-magnetisable material. In the context of the present invention, sufficiently far away means that distance where the strength of the magnetic field created by the MRI device 40 drops to an extent that makes it is essentially negligible. The distance adapter 39 may be, for example, an optic fibre, through which the laser beam 13 may be transmitted to the sample 32.

The control system 36′ controls the deflecting means 24′, the adjustable objective arm 38 and the MRI device 40. In this case the control system 36′ may also be an independent unit, e.g. a computer or microcontroller, or may include the other control units controlling the components of the combined imaging system 10′. In the latter case, one main control unit may perform the compilation and analysis of the data (e.g. such as the feedback information relating to position) provided by the other control units, and the forwarding of the appropriate control signals to the other control units. The control system 36′ may be built into the combined imaging system 10′, or it may be a separate device, or control software running on a separate device, e.g. a computer.

The control system 36′ has the preferable characteristics described in the case of control system 36.

Various modifications to the above disclosed embodiments will be apparent to a person skilled in the art without departing from the scope of protection determined by the attached claims.

1: Combined imaging system, characterised by that the combined imaging system (10, 10′) comprises a laser scanning microscope (50, 50′), and a measuring device with a lower resolution than the resolution of the laser scanning microscope (50, 50′) and that measures over a larger spatial scale than the spatial scale of the laser scanning microscope (50, 50′).

2: The combined imaging system according to claim 1, characterised by that the combined imaging system (10′) comprises an MRI device (40) as the measuring device with a lower resolution than the resolution of the laser scanning microscope (50′) and that measures over a larger spatial scale than the spatial scale of the laser scanning microscope (50′).

3: The combined imaging system according to claim 1, characterised by that the laser scanning microscope (50′) is a multiphoton laser scanning microscope.

4: The combined imaging system according to claim 2, characterised by that it comprises a control system (36′) for control the MRI device (40) and the laser scanning microscope (50′).

5: The combined imaging system according to claim 4, characterised by that the control system (36′) is an independent unit (for example, a computer or microcontroller) and/or may include other control units separately controlling the components of the combined imaging system (10′).

6: The combined imaging system according to claim 1, characterised by that it comprises a CT device, preferably a SPECT device (34) as the measuring device with a lower resolution than the resolution of the laser scanning microscope (50) and that measures over a larger spatial scale than the spatial scale of the laser scanning microscope (50).

7: The combined imaging system according to claim 6, characterised by that the laser scanning microscope (50) is a multiphoton laser scanning microscope.

8: The combined imaging system according to claim 6, characterised by that the laser scanning microscope (50) is a confocal laser scanning microscope.

9: The combined imaging system according to claim 6, characterised by that it contains a control system (36) serving for controlling the CT device, especially a SPECT device (34), and the laser scanning microscope (50).

10: The combined imaging system according to claim 9, characterised by that the control system (36) is an independent unit (for example, a computer or microcontroller) and/or may include other control units separately controlling the components of the combined imaging system (10).

11: MRI compatible laser scanning microscope, which comprises:
deflecting means (24′) for deflecting a laser beam (13),
objective (28′),
adjustable objective arm (38), and
at least one detector (30′)
characterised by that it also comprises a distance adapter (39) linking the objective (28′) to the adjustable objective arm (38), and at least the objective (28′), the adjustable objective arm (38), the distance adapter (39) and the at least one detector (30′) are made from non-magnetisable materials and the deflecting means (24′) is magnetically shielded.

12: The MRI compatible laser scanning microscope according to claim 11, characterised by that the laser scanning microscope is a multiphoton laser scanning microscope.

13: The MRI compatible laser scanning microscope according to claim 11, characterised by that the laser scanning microscope is a confocal laser scanning microscope.
